(19) United States
(12) Patent Application Publication
(10) Pub. No.: US 2011/0175204 A1
(43) Pub. Date: Jul. 21, 2011

(54) SEMICONDUCTOR DEVICE AND METHOD OF MANUFACTURING THE SAME

(76) Inventor: Kanako SAWADA, Yokohama-shi (JP)

(21) Appl. No.: 13/005,936

(22) Filed: Jan. 13, 2011

(30) Foreign Application Priority Data
Jan. 15, 2010 (JP) P2010-006456

(51) Int. Cl. H01L 29/06; H01L 21/302

(52) U.S. Cl. 257/618; 438/462; 257/E21.214; 257/E29.005

(57) ABSTRACT

According to one embodiment, a manufacturing method of a semiconductor device is disclosed. This method can include dicing along a predetermined line a laminated substrate which has a first substrate and a second substrate, one of which is made of a semiconductor substrate, mutually adhered with an adhesive layer interposed between them. The dicing process includes irradiating a laser beam to the adhesive layer along the dicing line to form scribe lines corresponding to the dicing line on the first and second substrates. And, the dicing process includes applying an impact to the laminated substrate to divide along the scribe lines.

### CROSS-REFERENCE TO RELATED APPLICATION

This application is based upon and claims the benefit of priority from Japanese Patent Application No. 2010-006456, filed on Jan. 15, 2010; the entire contents of which are incorporated herein by reference.

### FIELD

Embodiments described herein relate generally to a semiconductor device and a method of manufacturing the same.

### BACKGROUND

A semiconductor device configured to have a silicon substrate, on which semiconductor elements are formed, and a glass substrate adhered with an adhesive agent is used for mobile phones and digital cameras. For production of such semiconductor devices, a method has been used which includes preparing a laminated substrate having the glass substrate adhered to the silicon substrate, on which the multiple semiconductor elements are formed, with an adhesive agent and subsequently dividing the laminated substrate into multiple numbers of individual devices.

As a method of dividing the laminated substrate, it is common to use a blade having a cutting edge coated with diamond abrasive grains. According to this method, a silicon substrate is first cut by a blade (blade for silicon) suitable for cutting the silicon substrate. Then, a blade (blade for glass) which is narrower than the blade for silicon and suitable for cutting a glass substrate is inserted in the grooves formed by the previous cutting and cut the glass substrate from the silicon substrate side. Such different blades are used for cutting because the silicon and the glass substrates have significantly different properties, which cause large cracks, also referred to as chipping, near a dicing line when the silicon and the glass substrates are cut collectively using the blade for silicon or the blade for glass, resulting in decrease in number of devices obtainable from one substrate.

However, the above method of using the blades is hard to increase in number of devices obtainable from one substrate, since narrowing the width of the dicing line (i.e. kerf width) is limited by the fact that a blade has a certain thickness by itself and also one of the blades must be thicker than the other

Recently, there is also a proposal of a method of using a laser beam as a type of technology described above. In the method, the substrate is melted locally by the laser beam, so that the dicing line width can be made narrower in comparison with the blade method, and the number of semiconductor devices obtainable from one substrate can be increased. But, silicon and glass configuring the substrate are materials having very high brittleness, so that the substrate may be possibly broken when cut. Also, since an amount of scribing depth per scanning of the laser beam is small, it may be necessary to scan multiple times in order to cut one line. Thus, there is a problem of poor efficiency.

### BRIEF DESCRIPTION OF THE DRAWINGS

FIG. 1 is a perspective view showing a structure of a laminated substrate used in a first embodiment.

FIG. 2 is a plan view showing a production process of the semiconductor device according to the first embodiment.

FIG. 3 is a plan view showing a process subsequent to the process shown in FIG. 2.

FIG. 4 is a sectional view showing a process subsequent to the process shown in FIG. 3.

FIG. 5 is a sectional view showing a process subsequent to the process shown in FIG. 4.

FIGS. 6A and 6B are perspective views illustrating a irradiating process of a laser beam in the first embodiment.

FIG. 7 is a sectional view showing a process subsequent to the process shown in FIG. 5.

FIG. 8 is a sectional view showing a process subsequent to the process shown in FIG. 7.

FIG. 9 is a sectional view illustrating a manufacturing method of a semiconductor device applying a blade method.

### DETAILED DESCRIPTION

In general, according to one embodiment, a manufacturing method of a semiconductor device is disclosed. The method can include dicing along a predetermined line a laminated substrate which has a first substrate and a second substrate, one of which is made of a semiconductor substrate, mutually adhered with an adhesive layer interposed between them. The dicing process can include irradiating a laser beam to the adhesive layer along the dicing line to form scribe lines corresponding to the dicing line on the first and second substrates. The dicing process also can include applying an impact to the laminated substrate to divide along the scribe lines.

According to another embodiment, a semiconductor device can include a first substrate made of a semiconductor substrate, and a second substrate which is laminated on one surface of the first substrate with an adhesive layer interposed between them. The adhesive layer can include a portion altered by irradiating a laser beam.

### First Embodiment

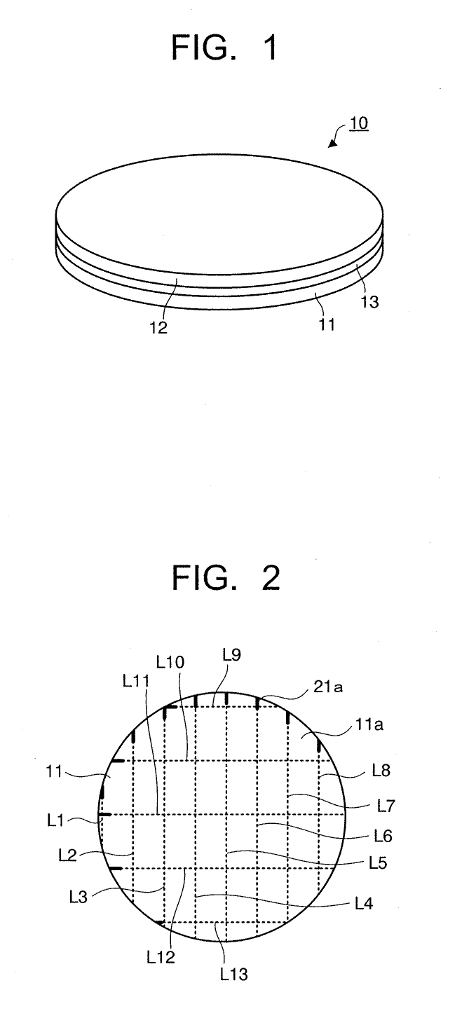

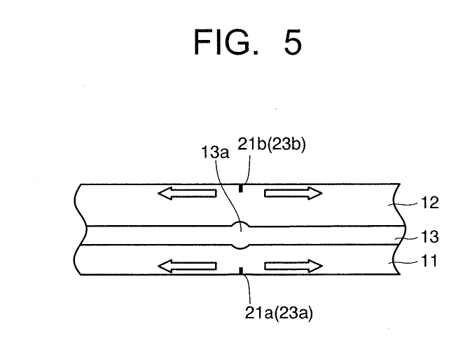

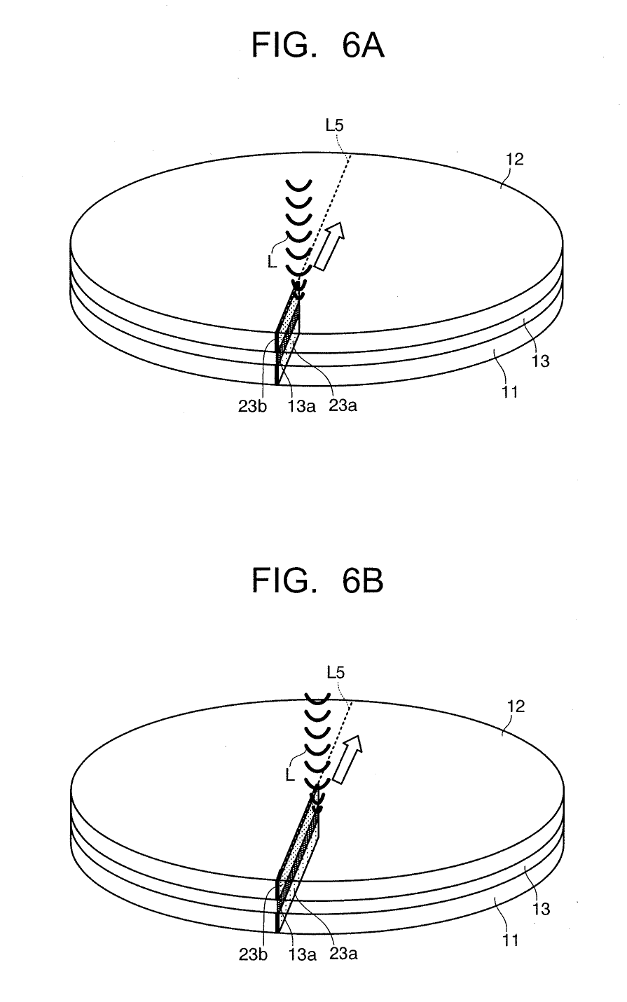

FIG. 1 is a perspective view showing the laminated substrate used in a first embodiment. FIG. 2 to FIG. 8 are views illustrating a manufacturing method of a semiconductor device in the embodiment. FIGS. 2, 3, 7 and 8 are plan views, FIGS. 4 and 5 are side views, and FIGS. 6A and 6B are perspective views.

In the embodiment, a laminated substrate 10 as shown in FIG. 1 is prepared first. In the laminated substrate 10, a first substrate 11 and a second substrate 12 are mutually adhered with an adhesive layer 13 between them as shown in FIG. 1. An example that the first substrate 11 is a silicon substrate and the second substrate 12 is a glass substrate is described below. Circuit patterns (not shown) for multiple semiconductor elements are formed on the back surface of the silicon substrate 11, which is on the side of the adhesive layer 13. A interconnection layer which is connected to the circuit patterns is formed on a surface (the surface on the side of the silicon substrate 11 of the laminated substrate 10) 11a of the silicon substrate 11. The adhesive layer 13 is made of an adhesive agent such as an epoxy-, a polyimide-, an acryl-, or a phenol-based adhesive. The silicon substrate 11 typically has a thickness of 50 to 800 μm, the glass substrate 12 typically has a thickness of 50 to 1000 μm, and the adhesive layer 13 typically has a thickness of 10 to 100 μm.

As shown in FIG. 2, dicing lines L1, L2, L3 . . . are arranged on the laminated substrate 10 for obtaining multiple semiconductor devices by dividing it. The example of FIG. 2 shows the eight parallel dicing lines L1 to L8 extending in a horizontal direction of the drawing and the five parallel dicing lines L9 to L13 perpendicular to the dicing lines L1 to L8.

In the embodiment, notches 21a are made at individual one ends of the dicing lines L1 to L13 on the side of the silicon substrate 11 by means of a diamond cutter or the like (FIG. 2).

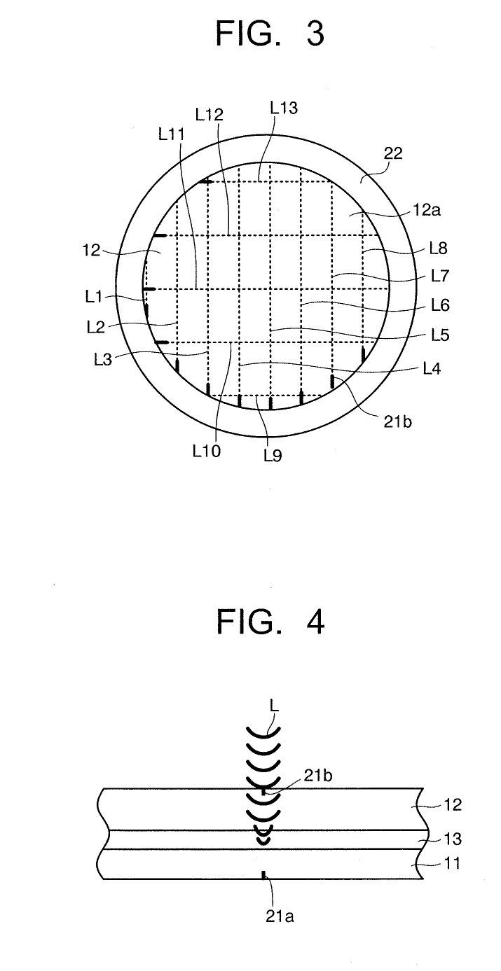

As shown in FIG. 3, the silicon substrate 11 is then fixed to a dicing tape 22 with the surface 11a of the silicon substrate 11 having the notches 21a on the down side, and same notches 21b are also formed on the glass substrate 12 by means of the diamond cutter or the like. Alternatively, the notches 21b may be made first on the glass substrate 12, and then the notches 21a may be made on the silicon substrate 11. The side to be fixed to the dicing tape 22 may also be a surface (the surface on the side of the glass substrate 12 of the laminated substrate 10) 12a of the glass substrate 12 having the notches 21b. For the dicing tape 22, there is used an adhesive tape, for example, those having a adhesive layer on a base made of a polyvinyl chloride resin (PVC), a polyethylene terephthalate resin (PET), a polyolefin resin (PO) or the like.

As shown in FIG. 4, a laser irradiation apparatus (not shown) then emits a laser beam L so as to focus on the adhesive layer 13 between the silicon and glass substrates 11 and 12 and below the notch 21b on one of the dicing lines L1 to L13, for example, on the dicing line L5 and moves a focal point in the adhesive layer 13 across the laminated substrate 10 from the portion below the notch 21b along the dicing line L5. The laser beam L may be irradiated from the side of the glass substrate 12 or from the side of silicon substrate 11. In the example of FIG. 4, the laser beam L is irradiated from the side of the glass substrate 12.

By irradiation of the laser beam L, a portion 13a is altered in the adhesive layer 13 along the dicing line L5 as shown in FIG. 5. In other words, when the laser beam L is irradiated to the adhesive layer 13, the adhesive layer 13 absorbs the energy of the laser beam L, which melt or vaporize the adhesive agent at the focal point and the vicinity to expand the volume. But, since the adhesive layer 13 is held between the silicon substrate 11 and the glass substrate 12 having high rigidity, its expansion is prevented. Therefore, a large tensile stress (as indicated by arrows in FIG. 5) generates in the silicon and glass substrates 11 and 12 in the vicinity of altered portion 13a. The notches 21a and 21b are formed at starting points of the dicing line L5 of the substrates 11 and 12, and the substrates 11 and 12 are made of a brittle material. Therefore, scribe lines 23a and 23b are formed on the substrates 11 and 12 along the dicing line L5 starting from the notches 21a and 21b. FIG. 5 draws the altered portion 13a in a swelled shape, but since heat deformation is suppressed in practice by the substrates 11 and 12, swelling should not occur. In FIGS. 4 and 5, the dicing tape 22 fixed to the surface 11a of the silicon substrate 11 is not shown.

The laser irradiation apparatus may be of any type so long as it comprises a laser generator and also it can melt or vaporize the adhesive agent at the focal point portion by focusing the laser beam L, generated from the laser generator, on the adhesive layer 13. The laser irradiation apparatus is selected appropriately depending on types of the substrate and the adhesive agent, their thickness and the like. The laser beam L typically has a wavelength of, but is not limited to, about 0.2 to 12 μm. The laser beam L used includes, for example, a carbon dioxide laser beam, a YAG laser beam, a UV laser beam or the like.

FIGS. 6A and 6B show a process of forming scribe lines, wherein the laser beam L is scanned to form the scribe lines on the silicon substrate 11 and the glass substrate 12 (silicon substrate-side scribe line 23a and glass substrate-side scribe line 23b) towards the direction indicated by the arrow along the dicing line L5 starting from the notches 21a and 21b respectively. The scribe lines 23a and 23b run from the altered portion 13a of the adhesive layer 13 to the individual surfaces or the vicinities of the surfaces of the substrates 11 and 12. FIGS. 6A and 6B show the dicing line L5 only, and the other dicing lines and the notches formed in one ends of such dicing lines are omitted.

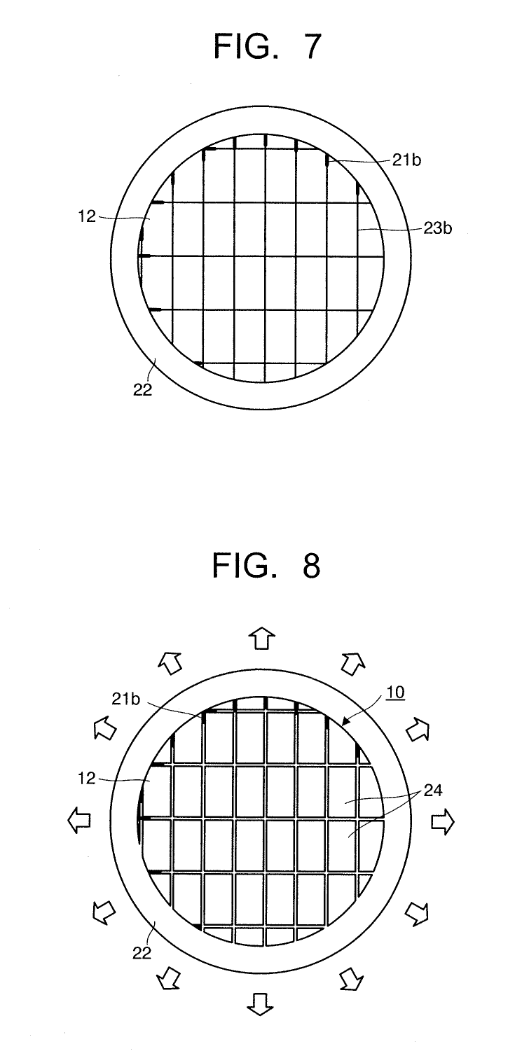

Similarly, the laser beam L is also irradiated to the other dicing lines L1 to L4 and L6 to L13 to form the altered portions 13a in the adhesive layer 13 along the individual dicing lines L1 to L4 and L6 to L13, thereby forming scribe lines on the substrates 11 and 12 along the individual dicing lines L1 to L4 and L6 to L13. FIG. 7 is a plan view of the laminated substrate 10 viewed from the side of the glass substrate 12 after the scribe lines are formed along all of the dicing lines L1 to L13 as described above. The scribe lines 23b are formed by the laser beam on the glass substrate 12 at positions corresponding to the dicing lines L1 to L13.

As shown in FIG. 8, the dicing tape 22 adhered to the surface 11a of the silicon substrate 11 is then expanded in a plane direction, and an impact is applied to the laminated substrate 10. As a result, the scribe lines 23a and 23b formed on the substrates 11 and 12 split off, and the altered portion 13a also falls in an almost cut off state because it is once melted or vaporized by the irradiation of the laser beam L. Thus, the laminated substrate 10 is divided into multiple semiconductor devices 24 having the semiconductor elements.

The above-described method alters selectively the adhesive layer 13 by the laser beam L, to form the scribe lines 23a and 23b in the substrates 11 and 12 from the altered portion 13a of the adhesive layer 13 to almost reach the individual surfaces. Then, an impact is applied to the laminated substrate 10 to cut off along the formed scribe lines 23a and 23b so as to divide the laminated substrate 10 into the individual semiconductor devices 24. Therefore, the dicing line can be narrowed to a width of 0 (zero) or almost 0 (zero), and more devices 24 can be obtained from one substrate than the method using a blade.

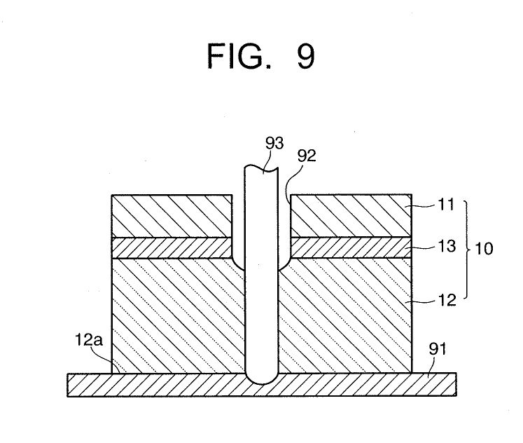

FIG. 9 shows an example of a method of producing multiple semiconductor devices from the laminated substrate 10 by applying the blade method. According to this method, after a dicing tape 91 is adhered to the surface 12a on the side of the glass substrate 12 side of the laminated substrate 10, the silicon substrate 11 is cut by means of a blade for silicon (not shown) suitable for cutting the silicon substrate 11. Subsequently, a blade for glass 93 narrower than the blade for silicon and suitable for cutting the glass substrate 12 is inserted into a groove 92 formed by previous cutting and then cut the glass substrate 12 from the side of the silicon substrate 11. According to this method, narrowing the width of the dicing line is limited to about 200 μm.

On the contrary, according to the method of the embodiment, because dividing into the individual semiconductor devices is accomplished by the cracks formed in the scribe lines 23a and 23b which are formed by the laser beam L in the substrates 11 and 12, so that a dicing width becomes substantially 0 (zero), and more devices can be obtained from one substrate than the blade method.

The laser beam L is not absorbed to the silicon substrate 11 or the glass substrate 12 but selectively to the adhesive layer 13. Therefore, the substrates 11 and 12 are not broken as in the case of using the conventional laser beam method, and multiple scanning of the laser beam is not required to cut a single line. Therefore, it becomes possible to produce high-quality semiconductor devices at an increased yield and with improved efficiency.

When division is accomplished according to the embodiment, the divided surfaces of the substrates 11 and 12 have a small roughness, while the irregularities of the divided surfaces of the adhesive layer 13 may be large (that is, the surface roughness may be large) because the adhesive layer 13 is cut off in a state almost decaying due to the alteration by the laser beam. Specifically, the divided surfaces of the altered portion 13a of the adhesive layer 13 may have the surface roughness Ry of 10 μm or more when measured by a stylus type surface roughness meter or a non-contact surface roughness meter using a laser beam. This surface roughness, however, does not impair the effect described above.

### Other Embodiments

In the first embodiment, as a dividing method of the laminated substrate 10 with the scribe lines 23a and 23b formed by the laser beam L, a so-called tape expansion method is used, wherein the dicing tape 22 previously adhered to the surface 11a of the silicon substrate 11 is expanded in a radial direction. Alternatively, it is possible to use another method, for example, a three-point bending method, a pushing-up method or the like. The three-point bending method performs three-point bending for the laminated substrate by pressing the blade against the scribe line formed by the laser beam. The pushing-up method pushes upward via the dicing tape by one or more pins or blades placed on the back surface. Whichever method is used, the laminated substrate 10 can be divided easily into multiple semiconductor devices 24 by applying an appropriate impact after forming the scribe lines 23a and 23b. In any of these method, as in the first embodiment, regardless of which method is used, the surface roughness of the divided surfaces of the silicon and glass substrates 11 and 12 may be small, while that of the adhesive layer 13 which is altered by irradiation of the laser beam have the surface roughness Ry of 10 μm or more when measured by a stylus type surface roughness meter or a non-contact surface roughness measuring meter using a laser beam. The tape expansion method described above is used preferably from the aspect that the method can accomplish division without touching the surface to which the dicing tape is not adhered, and that there is no possibility of chipping caused by mutual contact of scribed surfaces on dividing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device, comprising:
dicing along a predetermined line a laminated substrate which has a first substrate and a second substrate, one of which is made of a semiconductor substrate, mutually adhered with an adhesive layer interposed between them,
wherein the dicing process comprises:
(A) irradiating a laser beam to the adhesive layer along the dicing line to form scribe lines corresponding to the dicing line on the first and second substrates, and
(B) applying an impact to the laminated substrate to divide along the scribe lines.

2. The method according to claim 1,
wherein notches are formed in the starting points of the dicing lines at the individual outer peripheral portions of the first and second substrates prior to the process (A), and the laser beam is then irradiated starting from the notched portions.

3. The method according to claim 1,
wherein the laser beam is irradiated to melt or vaporize the adhesive agent in the process (A).

4. The method according to claim 1,
wherein the process (B) is performed by applying one selected from a tape expansion method, a three-point bending method and a pushing-up method.

5. The method according to claim 1,
wherein the first and second substrates have a different property.

6. The method according to claim 1,
wherein the first substrate is a silicon substrate, and the second substrate is a glass substrate.

7. The method according to claim 6,
wherein the silicon substrate has a thickness of 50 to 800 μm, and the glass substrate has a thickness of 50 to 800 μm.

8. The method according to claim 1,
wherein the adhesive layer is made of at least one selected from epoxy-, polyimide-, acryl- and phenol-based adhesive agents.

9. The method according to claim 1,
wherein the adhesive layer has a thickness of 10 to 100 μm.

10. The method according to claim 1,
wherein the laser beam is irradiated from the first substrate side and/or the second substrate side.

11. The method according to claim 1,
wherein the laser beam has a wavelength of 0.2 to 12 μm.

12. The method of a semiconductor device according to claim 1,
wherein the dicing line has a width of substantially 0 (zero).

13. A semiconductor device, comprising,
a first substrate made of a semiconductor substrate and a second substrate laminated on a surface of the first substrate with an adhesive layer between them,
wherein the adhesive layer has a portion which is altered by irradiation of a laser beam.

14. The device according to claim 13,
wherein the outer circumferential surface of the adhesive layer is configured of a divided surface of the altered portion.

15. The device according to claim 14,
wherein the divided surface of the altered portion has a surface roughness (Ry) of 10 μm or more.

16. The device according to claim 13,
wherein the altered portion is formed by melting or vaporizing the adhesive agent.

17. The device according to claim 13,
wherein the adhesive layer is made of at least one selected from epoxy-, polyimide-, acryl- and phenol-based adhesive agents.

18. The device according to claim 13,
wherein the first substrate is a silicon substrate and the second substrate is a glass substrate.

19. The semiconductor device according to claim 14,
wherein the silicon substrate has a thickness of 50 to 800 μm, and the glass substrate has a thickness of 50 to 800 μm.

20. The device according to claim 13,
wherein the adhesive layer has a thickness of 10 to 100 μm.
